(19) United States
(12) Patent Application Publication
(10) Pub. No.: US 2025/0218732 A1
(43) Pub. Date: Jul. 3, 2025

(54) SUBSTRATE TREATING APPARATUS AND METHOD

(71) Applicant: SEMES CO., LTD., Cheonan-si (KR)

(72) Inventors: Seong Gil LEE, Gyeonggi-do (KR); Yun Sang KIM, Gyeonggi-do (KR); Wan Jae PARK, Gyeonggi-do (KR); Myoung Sub NOH, Gyeonggi-do (KR); Jae Hwan KIM, Gyeonggi-do (KR); Seong Hak BAE, Gyeongsangnam-do (KR)

(73) Assignee: SEMES CO., LTD., Cheonan-si (KR)

(21) Appl. No.: 18/958,103

(22) Filed: Nov. 25, 2024

(30) Foreign Application Priority Data
Dec. 27, 2023 (KR) 10-2023-0192005

(51) Int. Cl. H01J 37/32

(52) U.S. Cl. CPC H01J 37/32449; H01J 37/32834; H01J 2237/334

(57) ABSTRACT

A substrate treating apparatus includes: a support unit supporting a substrate; a process gas supply unit supplying a process gas for treating the substrate; a chamber unit in which a processing space accommodating the support unit is formed and into which the process gas is introduced; and a first gas supply module supplying a first gas for regulating the density of effluents from the process gas, wherein the chamber unit includes a first gas exhaust hole discharging the first gas toward the substrate.

### CROSS-REFERENCE TO RELATED APPLICATION

This application claims priority from Korean Patent Application No. 10-2023-0192005 filed on Dec. 27, 2023 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus and method.

### 2. Description of the Related Art

In the manufacture of semiconductor devices or display devices, a substrate treating process using plasma may be employed. The substrate treating process using plasma can be categorized into a capacitively coupled plasma (CCP) method, an inductively coupled plasma (ICP) method, and a hybrid method combining both, depending on how to generate plasma. Additionally, dry cleaning or dry etching can be performed using plasma.

Dry cleaning and dry etching are isotropic etching processes and involve minimal pattern collapse and reduced plasma-induced damage. However, as substrates become larger and patterns become more complex, the etch rate and/or uniformity may vary depending on the position on each substrate, requiring improvements.

### SUMMARY

Aspects of the present disclosure provide a substrate treating apparatus and method capable of controlling the etch rate of silicon and/or the uniformity of a substrate according to the position on the substrate.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a support unit supporting a substrate; a process gas supply unit supplying a process gas for treating the substrate; a chamber unit in which a processing space accommodating the support unit is formed and into which the process gas is introduced; and a first gas supply module supplying a first gas for regulating the density of effluents from the process gas, wherein the chamber unit includes a first gas exhaust hole discharging the first gas toward the substrate.

According to another aspect of the present disclosure, a substrate treating method includes: providing a substrate treating apparatus, the substrate treating apparatus including: a support unit supporting a substrate having a center region and an edge region at a periphery of the center region; a process gas supply unit supplying a process gas including a fluorine-containing gas to treat the substrate; a chamber unit in which a processing space accommodating the support unit is formed, into which the process gas is introduced, and which includes a first gas exhaust hole discharging a first gas for regulating a density of effluents from the process gas toward the substrate; a first gas supply module supplying the first gas; an upper electrode connected to the process gas supply unit and having a first supply hole through which the process gas flows; an ion blocker disposed below the upper electrode, with a first space formed between the ion blocker and the upper electrode to receive the process gas, the ion blocker including a first through-hole through which effluents from the process gas are discharged; and a shower head provided above the chamber unit, with a second space formed between the shower head and the ion blocker, the shower head including a second through-hole discharging effluents from the process gas from above the processing space; supplying the first gas to the substrate through the first gas exhaust hole, not from above the shower head; and supplying the process gas, wherein the first gas includes a hydrogen-containing gas that generates a fluorine scavenging effect.

According to another aspect of the present disclosure, a substrate treating apparatus includes: a support unit supporting a substrate having a center region and an edge region at a periphery of the center region and including an electrode plate serving as a lower electrode; a process gas supply unit supplying a process gas including a fluorine-containing gas to treat polysilicon formed on the substrate; a chamber unit in which a processing space accommodating the support unit is formed and into which the process gas is introduced; a first gas supply module supplying a first gas for regulating a density of effluents from the process gas; an upper electrode connected to the process gas supply unit and having a first supply hole through which the process gas flows; an ion blocker disposed below the upper electrode, with a first space formed between the ion blocker and the upper electrode to receive the process gas, the ion blocker including a first through-hole through which effluents from the process gas are discharged; and a shower head provided above the chamber unit, with a second space formed between the shower head and the ion blocker, the shower head including a second through-hole discharging effluents from the process gas from above the processing space, wherein the chamber unit includes: a chamber in which the processing space is formed; and a liner surrounding an inner circumferential surface of the chamber, with a plurality of first gas exhaust holes formed along its circumference to discharge the first gas toward the substrate, and including a first flow path in communication with the plurality of first gas exhaust holes, through which the first gas flows, the first flow path being connected to the first gas supply module, the first gas supply module includes a first gas line through which the first gas flows, the first gas line supplying the first gas to the edge region of the substrate to equalize an etch rate between the center region and the edge region, the first gas line includes: an orifice forming a second fluid pressure that discharges the first gas to the edge region without forming a first fluid pressure that discharges the first gas to the center region; and a valve forming a second flow rate that discharges the first gas to the edge region without forming a first flow rate that discharges the first gas to the center region, and the first gas includes a hydrogen-containing gas that generates a fluorine scavenging effect and includes at least one of H2, HBr, NH3, or CH4.

According to the aforementioned and other embodiments of the present disclosure, by locally supplying a hydrogen-containing gas to the edge region of a substrate from a lateral side of the substrate via the chamber unit when fluorine radicals react with polysilicon to etch it into the form of silicon tetrafluoride (SiF₄(g)), the etch rate in the edge region of the substrate can be controlled, thereby improving the uniformity of the substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram illustrating a semiconductor device manufacturing facility equipped with a substrate treating apparatus according to some embodiments of the present disclosure;

FIG. 2 is a diagram illustrating a substrate treating apparatus according to some embodiments of the present disclosure;

FIG. 3 is a diagram illustrating a chamber unit of the substrate treating apparatus according to some embodiments of the present disclosure;

FIG. 4 is a flowchart illustrating a substrate treating method according to some embodiments of the present disclosure;

FIG. 5 is a diagram showing the timing at which reaction gases are supplied in accordance with the substrate treating method according to some embodiments of the present disclosure;

FIG. 6 is a diagram illustrating a state in which a first gas is supplied in accordance with the substrate treating method according to some embodiments of the present disclosure;

FIG. 7 is a diagram illustrating a state in which reaction gases are supplied in accordance with the substrate treating method according to some embodiments of the present disclosure; and

FIG. 8 is a diagram showing the etch rate of a substrate in a comparative example where a hydrogen-containing gas is not supplied.

### DETAILED DESCRIPTION

The following detailed description provides preferred embodiments of the present disclosure with reference to the accompanying drawings. The advantages and features of the present disclosure, as well as the methods of achieving them, will become apparent by referring to the detailed embodiments described below in conjunction with the drawings. However, the present disclosure is not limited to the embodiments disclosed herein and can be implemented in various forms. The provided embodiments are intended to fully disclose the invention and to convey the complete scope of the invention to those skilled in the art. The invention is defined only by the scope of the claims. Throughout the specification, like reference numerals refer to like elements.

The terminology used in this specification is intended to describe embodiments and is not intended to limit the invention. In this specification, the singular includes the plural unless otherwise specifically stated. The terms “comprises” and/or “comprising,” as used herein, do not exclude the presence or addition of one or more other elements, steps, operations, and/or features.

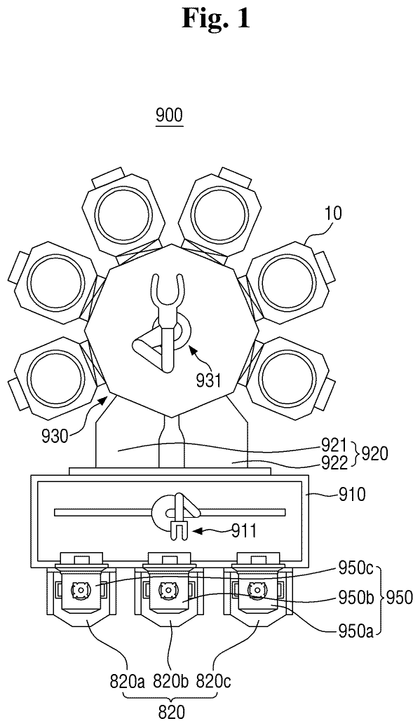

FIG. 1 is a diagram illustrating a semiconductor device manufacturing facility equipped with a substrate treating apparatus according to some embodiments of the present disclosure.

Referring to FIG. 1, a semiconductor device manufacturing facility 900 may include load port modules 820, an index module 910, load lock chambers 920, a transfer chamber 930, and process chambers. The process chambers will hereinafter be referred to as substrate treating apparatuses 10.

The semiconductor device manufacturing facility 900 is a system that treats a plurality of substrates W (e.g., wafers) through various processes such as etching and cleaning processes. The semiconductor device manufacturing facility 900 may be implemented as a multi-chamber-type substrate treating system including first and second transfer robots 911 and 931 and a plurality of substrate treating apparatuses 10, which are substrate treating modules arranged around the first and second transfer robots 911 and 931 to transport the substrates W.

The load port modules 820 are where containers 950 (e.g., front opening unified pods (FOUPs)), loaded with the substrates W, are placed. A plurality of load port modules 820 may be disposed at the front of the index module 910.

When a plurality of load port modules 820 are disposed at the front of the index module 910, the containers 950 mounted on the respective load port modules 820 may be loaded with different items. For example, if three load port modules 820 are disposed at the front of the index module 910, a first container 950a mounted on a first load port 820a on the left may carry wafer-type sensors (not illustrated), a second container 950b mounted on a second load port 820b in the middle may carry substrates W, and a third container 950c mounted on a third load port 820c on the right may carry consumable parts (not illustrated). However, the present disclosure is not limited to this example. Alternatively, the first, second, and third containers 950a, 950b, and 950c mounted on the first, second, and third load ports 820a, 820b, and 820c, respectively, may all carry the same items as needed.

The index module 910 is positioned between the load port modules 820 and the load lock chambers 920 and serves as an interface to transfer the substrates W between the containers 950 on the load port modules 820 and the load lock chambers 920. The index module 910 may be implemented as a front end module (FEM), but is not limited thereto.

The index module 910 may be equipped with the first transfer robot 911, which is for transferring the substrates W. The first transfer robot 911 may operate in an atmospheric environment and transfer the substrates W between the containers 950 and the load lock chambers 920.

The load lock chambers 920 may serve as buffers between the input and output ports of the semiconductor device manufacturing facility 900. The load lock chambers 920 may include buffer stages where the substrates W temporarily stand by.

A plurality of load lock chambers 920 may be provided between the index module 910 and the transfer chambers 930. In this embodiment, for example, two load lock chambers 920, i.e., first and second load lock chambers 921 and 922, may be provided between the index module 910 and the transfer chambers 930.

The first and second load lock chambers 921 and 922 may be disposed horizontally between the index module 910 and the transfer chamber 930. For example, the first and second load lock chambers 921 and 922 may be provided in a symmetrical single-layer structure where they are disposed side by side in a left-right direction. Alternatively, the first and second load lock chambers 921 and 922 may be disposed vertically between the index module 910 and the transfer chamber 930.

The first load lock chamber 921 may transfer the substrates W from the index module 910 to the transfer chamber 930, and the second load lock chamber 922 may transfer the substrates W from the transfer chamber 930 back to the index module 910. However, the present disclosure is not limited to this. Alternatively, the first load lock chamber 921 may transfer the substrates W from the transfer chamber 930 to the index module 910, and the second load lock chamber 922 may transfer the substrates W from the index module 910 to the transfer chamber 930.

The load lock chambers 920 may load or unload the substrates W through the second transfer robot 931 in the transfer chamber 930. The load lock chambers 920 may also load or unload the substrates W through the first transfer robot 911 in the index module 910.

The load lock chambers 920 may maintain pressure by switching their internal environment between a vacuum and atmospheric pressure using gate valves or similar mechanisms. Through this, the load lock chambers 920 can prevent changes in the internal pressure of the transfer chamber 930.

Specifically, when the substrates W are loaded or unloaded by the second transfer robot 931, the load lock chambers 920 may be set to a vacuum environment identical or similar to that of the transfer chamber 930. Additionally, when the substrates W are loaded or unloaded by the first transfer robot 911 (i.e., when receiving unprocessed substrates W from the first transfer robot 911 or transferring processed substrates W to the index module 910), the load lock chambers 920 may be set to an atmospheric environment.

The transfer chamber 930 is for transferring the substrates W between the load lock chambers 920 and the substrate treating apparatuses 10. To this end, the transfer chamber 930 may include at least one second transfer robot 931.

The second transfer robot 931 transfers unprocessed substrates W from the load lock chambers 920 to the substrate treating apparatuses 10, or transfers processed substrates W from the substrate treating apparatuses 10 back to the load lock chambers 920. The sides of the transfer chamber 930 may be connected to the load lock chambers 920 and the substrate treating apparatuses 10.

Meanwhile, the second transfer robot 931 may operate in a vacuum environment and may be designed to rotate freely.

The substrate treating apparatuses 10 may process the substrates W. The substrate treating apparatuses 10 may be implemented as etching or cleaning chambers that use an etching or cleaning process to treat the substrates W. For example, the substrate treating apparatuses 10 may be configured as plasma reaction chambers that perform etching or cleaning using a plasma process. The substrate treating apparatuses 10 will hereinafter be described as performing etching, but are not limited thereto. Alternatively, the substrate treating apparatuses 10 may also perform cleaning.

A plurality of substrate treating apparatuses 10 may be disposed around the transfer chamber 930. In this configuration, the substrate treating apparatuses 10 may receive the substrates W from the transfer chamber 930, process the substrates W, and then supply the processed substrates W back to the transfer chamber 930.

The substrate treating apparatuses 10 may be formed in a cylindrical shape. The substrate treating apparatuses 10 may be formed of alumite with an anodized oxide film formed on its surface, and the interior of the substrate treating apparatuses 10 may be hermetically sealed. Meanwhile, the substrate treating apparatuses 10 may also be formed in shapes other than cylindrical.

The substrate treating apparatuses 10 may use, for example, fluorine radicals to remove silicon (or polysilicon) from the areas designated for gate metals before depositing the gate metals in a logic product.

The substrate treating apparatuses 10 will hereinafter be described in further detail with reference to the drawings.

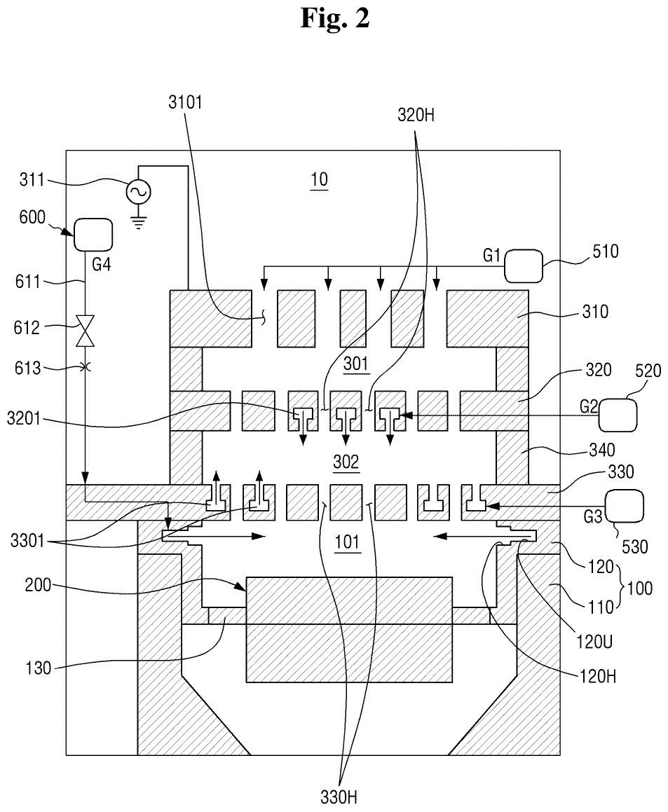

FIG. 2 is a diagram illustrating a substrate treating apparatus according to some embodiments of the present disclosure.

Referring to FIG. 2, a substrate treating apparatus 10 according to some embodiments of the present disclosure may include a chamber unit 100, a support unit 200, an electrode module (310, 320, 330, and 340), a gas supply unit (510, 520, and 530), and a first gas supply module 600.

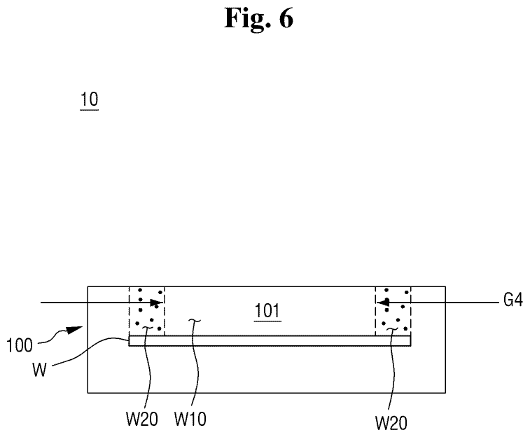

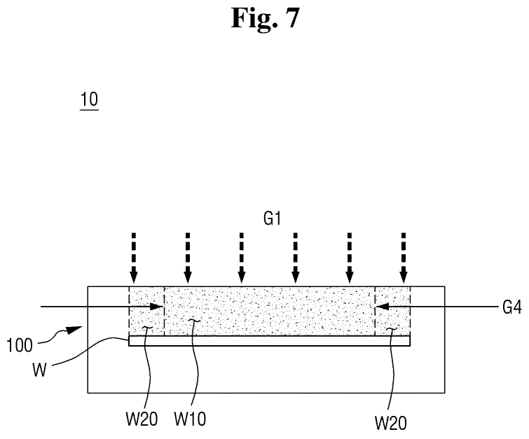

The chamber unit 100 may provide a processing space 101 where a substrate W (refer to FIG. 6) is treated. An opening (not illustrated) that serves as an entrance/exit for the substrate W may be formed on one sidewall of the chamber unit 100. This opening can be opened and closed by a door. An exhaust port (not illustrated) may be installed on the bottom surface of the chamber unit 100. The exhaust port may function as an outlet for discharging by-products generated in the processing space 101 to the outside of the chamber unit 100.

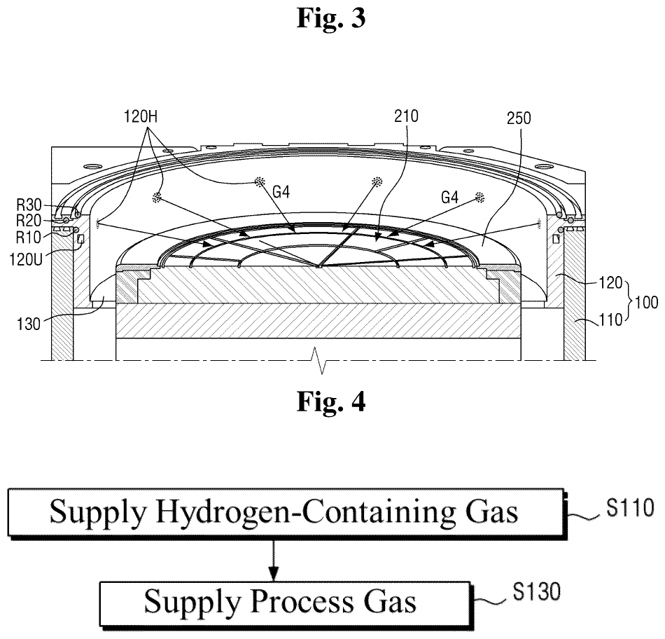

For example, the chamber unit 100 may include a chamber 110, a liner 120, and a baffle 130. The chamber 110 and the liner 120 will be described later with reference to FIG. 3.

The baffle 130 may be located between the inner wall of the chamber 110 (and/or the liner 120) and the support unit 200. The baffle 130 may be provided in a ring shape. The baffle 130 may have a plurality of holes (not illustrated) formed therein, allowing process gas supplied within the chamber unit 100 to pass through these holes and be exhausted through the exhaust port. The flow of process gas may be controlled depending on the shape of the baffle 130 and its holes.

The support unit 200 may be installed within the processing space 101, and may support the substrate W. For example, the support unit 200 may include a support plate 210 and a ring member 250 (refer to FIG. 3).

The support plate 210 may be an electrostatic chuck that supports the substrate W using electrostatic force, but is not limited thereto. For example, the electrostatic chuck may include a dielectric plate on which the substrate W is placed, a first electrode (not illustrated) installed within the dielectric plate to provide electrostatic force to attract the substrate W to the dielectric plate, and an electrode plate (not illustrated) that functions as a lower electrode.

The ring member 250 may be disposed at the edge region of the support plate 210. The ring member 250 may have a ring shape. The ring member 250 may be provided to surround the support plate 210. For example, the ring member 250 may function as a focus ring.

The electrode module (310, 320, 330, and 340) may include an upper electrode 310, an ion blocker 320, a shower head 330, and a heater ring 340, and may function as a capacitively coupled plasma (CCP) source together with the electrode plate of the support plate 210. The plasma source may excite the process gas in the chamber 110 into a plasma state.

For example, the upper electrode 310 and the lower electrode (e.g., the electrode plate of the support plate 210) may be disposed vertically parallel to each other relative to the processing space 101. One of the upper electrode 310 and the lower electrode may receive high-frequency power, while the other may be grounded. An electromagnetic field may be formed in the space between the upper electrode 310 and the lower electrode, and the process gas supplied to the processing space 101 between the upper electrode 310 and the lower electrode may be excited into a plasma state.

For example, the high-frequency power applied to the upper electrode 310 may range from 13 MHz to 100 MHz and from 50 W to 1000 W, but is not limited thereto.

A first space 301 may be disposed between the upper electrode 310 and the ion blocker 320, and a second space 302 may be disposed between the ion blocker 320 and the shower head 330. The processing space 101 may be positioned below the shower head 330.

For example, the high-frequency power source 311 may be connected to the upper electrode 310, and the ion blocker 320 may be connected to a constant voltage (e.g., ground voltage). A plurality of first supply holes 3101 may be formed in the upper electrode 310. The first supply holes 3101 in the upper electrode 310 may be connected to a process gas supply unit 510 to supply process gas G1 to the first space 301. The process gas G1 supplied to the first space 301 may be excited into a plasma state by the electromagnetic field generated between the upper electrode 310 and the ion blocker 320.

The process gas G1 excited into a plasma state (i.e., plasma effluents) may include radicals, ions, and/or electrons. The process gas G1 may vary depending on a target material. For example, the target material may be (poly)silicon formed on the substrate W. To etch silicon, the target material, the process gas G1 may contain fluorine (F) gas, may be F or nitrogen trifluoride (NF₃), and may further contain inert gases (e.g., N₂, He, and Ar).

The ion blocker 320 may be formed of a conductive material and may have, for example, a plate shape such as a disk. The ion blocker 320 may be connected to a constant voltage, but is not limited thereto. A plurality of first through-holes 320H extending vertically may be formed in the ion blocker 320. Among the plasma effluents, radicals or uncharged neutral species may pass through the first through-holes 320H in the ion blocker 320, whereas charged species (i.e., ions) may be difficult to pass through the first through-holes 320H. For example, if the process gas G1 is F or NF₃, the fluorine-containing radicals (e.g., F* or NF₃*) may pass through the ion blocker 320.

The shower head 330 may be formed of a conductive material and may have a plate shape, such as a disk. The shower head 330 may be connected to a constant voltage but is not limited thereto. A plurality of second through-holes 330H extending vertically may be formed in the shower head 330. Thus, the radicals passing through the first through-holes 320H of the ion blocker 320 may pass through the second through-holes 330H of the shower head 330 and may be supplied to the processing space 101.

The heater ring 340 may be disposed between the ion blocker 320 and the shower head 330 and may surround the second space 302. The heater ring 340 is for controlling the temperature of the shower head 330 and may not be installed within the shower head 330. By installing the heater ring 340 outside the shower head 330, the shower head 330 can be made more compact.

The gas supply unit (510, 520, and 530) may supply the process gas G1. In accordance with a modification of this embodiment, the gas supply unit (510, 520, and 530) may additionally supply first reaction gas G2 and/or second reaction gas G3. For example, the gas supply unit (510, 520, and 530) may include the process gas supply unit 510 for supplying the process gas G1, a first reaction gas supply unit 520 for supplying the first reaction gas G2, and a second reaction gas supply unit 530 for supplying the second reaction gas G3.

That is, the gas supply unit (510, 520, and 530) may be configured to supply the process gas G1, the first reaction gas G2, and the second reaction gas G3 individually. For example, the gas supply unit (510, 520, and 530) may include a plurality of supply lines (not illustrated) and a plurality of gas storage units (not illustrated) connected individually to the supply lines, where one supply line may be connected to the first supply holes 3101 of the upper electrode 310, another supply line may be connected to a plurality of first supply ports 3201 of the ion blocker 320, and yet another supply line may be connected to a plurality of second supply ports 3301 of the shower head 330.

Here, the first supply ports 3201 and the second supply ports 3301, which have not yet been explained, may be provided to supply the first and second reaction gases G2 and G3. In other words, in accordance with a modification of this embodiment, the process gas G1 may be mixed with other materials, such as the first and second reaction gases G2 and G3.

To this end, the ion blocker 320 may have a plurality of first supply ports 3201 to supply the first reaction gas G2 to the second space 302. However, since this embodiment involves an etching process for silicon, the first supply ports 3201 are not necessarily required and may be omitted.

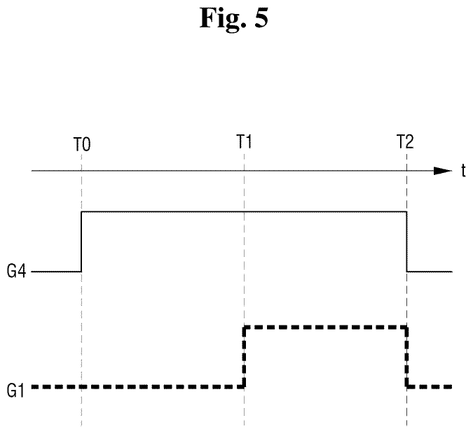

Referring to FIG. 5, if silicon oxide is the target material, the first and second reaction gases G2 and G3 may be essential for a substrate treating process and may thus be supplied during a first process time between T0 and T1 and during a second process time between T1 and T2. However, as in this embodiment, the target material is silicon, the first and second reaction gases G2 and G3 may be supplied optionally. Consequently, the supply of the first and second reaction gases G2 and G3 may be optional in the etching process for silicon. Thus, in accordance with a modification of this embodiment, the first supply ports 3201 and the second supply ports 3301 may be omitted or provided as needed. However, it may be preferable to provide the first supply ports 3201 to allow for various treatments for the substrate W or enable various process designs using a single substrate treating apparatus 10.

When a plurality of first supply ports 3201 are formed, they may not be distributed across the entire surface of the ion blocker 320 but may rather be located only in a particular area. For example, referring to FIG. 6, the first supply ports 3201 may be formed to correspond with a central region W10 of the substrate W.

Additionally, the shower head 330 may have a plurality of second supply ports 3301 for supplying the second reaction gas G3 to the second space 302. However, as this embodiment involves a silicon etching process, the second supply ports 3301 are not strictly required and may be omitted. However, similar to the first supply ports 3201, it may be preferable to include the second supply ports 3301 to allow for various process designs.

When a plurality of second supply ports 3301 are formed, they may not be distributed across the entire surface of the shower head 330 but may rather be formed to correspond with a particular area, such as an edge region W20 of the substrate W.

The first and second reaction gases G2 and G3 may be of the same type or of different types depending on the design. Since the first and second reaction gases G2 and G3 can be provided to the processing space 101 in an unexcited state (i.e., non-plasma state), they may be supplied ahead of the process gas G1 during the first process time (between T0 and T1), which is a plasma-off state.

Moreover, the first and second reaction gases G2 and G3 may vary depending on the types of the target material and the process gas G1. For example, if the target material is silicon or silicon oxide and the process gas G1 is NF₃, the first and second reaction gases G2 and G3 may be ammonia gas (NH₃) and may further contain an auxiliary gas (e.g., a nitrogen gas (N₂) or an inert gas such as He).

When the first and second reaction gases G2 and G3 are supplied, the radicals (e.g., fluorine-containing radicals such as F* or NF₃*) passing through the ion blocker 320 may be mixed in the second space 302 with the first reaction gas G2, provided through the first supply ports 3201 of the ion blocker 320, and the second reaction gas G3, provided through the second supply ports 3301 of the shower head 330.

The radicals (e.g., F* or NF₃*) in the second space 302 (or the mixture of F* or NF₃* and the first and second reaction gases G2 and G3) may flow downward through the second through-holes 330H into the processing space 101.

When the second reaction gas G3 is supplied, it may flow upward into the second space 302 through the second supply ports 3301 and then flow downward through the second through-holes 330H into the processing space 101, but the present disclosure is not limited thereto.

Meanwhile, the first supply ports 3201 are not limited to being formed in the ion blocker 320, and the second supply ports 3301 are not limited to being formed in the shower head 330. Alternatively, in another example, both the first supply ports 3201 and the second supply ports 3301 may be formed in the shower head 330, with their outlets directed downward. Consequently, the first and second reaction gases G2 and G3 can be supplied directly to the processing space 101, allowing for various modifications.

The chamber unit 100 and the first gas supply module 600 will hereinafter be described with reference to the drawings.

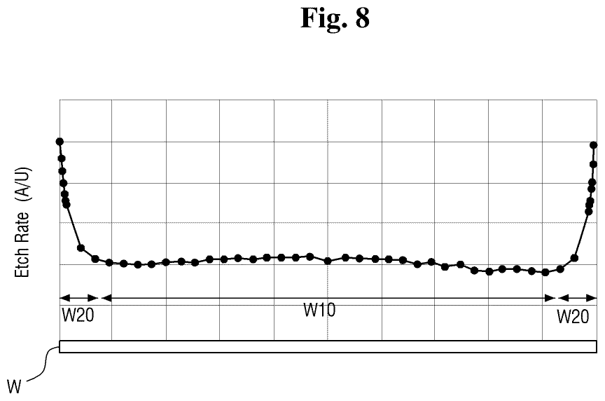

FIG. 3 is a diagram illustrating the chamber unit of the substrate treating apparatus according to some embodiments of the present disclosure. Additionally, FIG. 8 is a diagram showing the etch rate of a substrate in a comparative example where a hydrogen-containing gas is not supplied.

Referring to FIG. 3 and further to FIG. 2, the chamber 110 may form the processing space 101 and may have a cylindrical shape. The shower head 330, the ion blocker 320, and the upper electrode 310 may be sequentially provided in a bottom-to-top direction to allow the inflow of the process gas G1.

The liner 120 may have a cylindrical shape with open top and bottom surfaces. The liner 120 may be positioned to contact the inner surface of the chamber 110. The liner 120 can protect the inner wall of the chamber 110 from arc discharge damage and prevent impurities generated during a substrate treating process from being deposited on the inner wall of the chamber 110. The liner 120 may include a material such as yttria (Y₂O₃), but is not limited thereto.

The upper end of the liner 120 may be bent outwardly such that the liner 120 may be mounted on the upper end of the chamber 110 while surrounding the inner circumferential surface of the chamber 110, but the present disclosure is not limited thereto. A plurality of O-rings R10, R20, and R30 may be provided between the liner 120 and the chamber 110 and between the liner 120 and the shower head 330 to ensure sealing.

Furthermore, the liner 120 may be formed with a plurality of first gas exhaust holes 120H and a first flow path 120U to supply a first gas G4.

The first gas exhaust holes 120H may be formed along the circumference of the liner 120 to discharge the first gas G4 toward the substrate W. The first gas exhaust holes 120H may be configured as a cluster of holes. In this embodiment, the first gas exhaust holes 120H are illustrated as a circular cluster of holes, but the present disclosure is not limited thereto. Alternatively, the first gas exhaust holes 120H may be a ring-shaped cluster of holes along the perimeter of the substrate W to facilitate the discharge of the first gas G4 toward the edge region W20 of the substrate W.

The first flow path 120U may connect with both the first gas exhaust holes 120H and the first gas supply module 600, allowing the first gas G4 supplied by the first gas supply module 600 to flow through the first gas exhaust holes 120H. For example, the first flow path 120U may be configured as a ring-shaped channel within the liner 120.

However, the present disclosure is not limited to this. Alternatively, in another example, the inner wall of the shower head 330 may be provided to form part of the circumferential wall of the first flow path 120U, such that a portion of the outer sidewall of the liner 120 facing the shower head 330 may be recessed, forming the first flow path 120U. That is, various modifications for routing the first gas G4 are enabled.

The first gas supply module 600 may supply the first gas G4, which regulates the density of the effluents from the process gas G1, and may include a first gas line 611.

Here, the first gas G4 may include a hydrogen-containing gas that generates a fluorine scavenging effect, such as at least one of H₂, HBr, NH₃, or CH₄.

The first gas line 611 may allow the first gas G4 to pass therethrough, and the fluid pressure and flow rate of the first gas G4 may be determined such that the etch rate of the process gas G1 may be equalized in both the center region W10 and the edge region W20.

For example, the fluid pressure and flow rate of the first gas G4 may be determined such that the density of the process gas G1 may be lower in the edge region W20 than in the center region W10.

Specifically, as shown in FIG. 8, if the first gas G4 is not supplied and the density of the process gas G1 is not controlled, i.e., if the density of the process gas G1 is the same in both the edge region W20 and the center region W10 of the substrate W, then there is a risk of excessive silicon etching/cleaning occurring in the edge region W20 due to the absence of the target material for a silicon etching reaction on the outer side of the edge region W20, unlike in the center region W10.

According to this embodiment, to control the fluid pressure and flow rate of the first gas G4, the first gas line 611 may include an orifice 613 and a valve 612.

The orifice 613, which is a pressure control unit, may form a second fluid pressure that discharges the first gas G4 to the edge region W20 without forming a first fluid pressure that discharges the first gas G4 to the center region W10.

The valve 612 may be provided as a flow control valve, enabling the first gas G4 to achieve a second flow rate that discharges the first gas G4 to the edge region W20 without forming a first flow rate that discharges the first gas G4 to the center region W10.

A substrate treating method, as a process for treating the substrate W in the processing space 101, will hereinafter be described with reference to the drawings.

FIG. 4 is a flowchart illustrating a substrate treating method according to some embodiments of the present disclosure, and FIG. 5 is a diagram showing the timing at which reaction gases are supplied in accordance with the substrate treating method according to some embodiments of the present disclosure. FIG. 6 is a diagram illustrating a state in which a first gas is supplied in accordance with the substrate treating method according to some embodiments of the present disclosure, and FIG. 7 is a diagram illustrating a state in which reaction gases are supplied in accordance with the substrate treating method according to some embodiments of the present disclosure.

Referring to FIGS. 4 through 7, after providing the substrate treating apparatus 10, the substrate treating method may include a step S110 of supplying the first gas G4, which is a hydrogen-containing gas, to the substrate W and a step S130 of supplying the process gas G1.

Here, the substrate treating apparatus 10 is the same as described above, and thus, a description thereof will be omitted.

Referring to FIGS. 4 through 6, after providing the substrate treating apparatus 10, the first gas G4 may be supplied to the processing space 101.

In other words, during the first process time (between T0 and T1), the plasma is in an off state, and the first gas G4 is supplied to the substrate W in the processing space 101. The first gas G4 may be supplied at a second fluid pressure and a second flow rate such that the first gas G4 may be provided to the edge region W20 of the substrate W, but not to the center region W10 of the substrate W.

Here, the first gas G4 may be supplied not from the top of the shower head 330 but through the first gas exhaust holes 120H of the liner 120, and may thus be supplied to the side rather than to the top of the substrate W.

Although the supply of the first reaction gas G2 and/or the second reaction gas G3 may be omitted, if supplied in accordance with a modification of this embodiment, the first reaction gas G2 and/or the second reaction gas G3 may be provided concurrently with the first gas G4.

Referring to FIGS. 4, 5, and 7, during the second process time (between T1 and T2), following the first process time, the supply of the first gas G4 may be continued while the process gas G1 may be supplied to the first space 301.

When the process gas G1 is supplied to the first space 301, high-frequency power 311 may be supplied to the upper electrode 310 to place plasma in an on state (i.e., to generate plasma), thereby exciting the process gas G1 into a plasma form in the first space 301. Consequently, plasma effluents, such as radicals, ions, and/or electrons, may be generated.

The ions may be filtered by the ion blocker 320, while the remaining plasma effluents may pass through the ion blocker 320. The plasma effluents that pass through the ion blocker 320 (i.e., fluorine-containing radicals such as F*, NF₃*, etc.) may then flow through the second space 302 and may be supplied to the processing space 101.

In accordance with a modification of this embodiment, during the second process time, the ion blocker 320 and/or the shower head 330 may supply the first reaction gas G2 and the second reaction gas G3 to the processing space 101. That is, the supply of the first and second reaction gases G2 and G3 may be omitted during both the first process time and the second process time, but in accordance with a modification of this embodiment, the supply of the first and second reaction gases G2 and G3 may be continued even during the second process time, if the first and second reaction gases G2 and G3 are supplied during the first process time.

Through the second through-holes 330H of the shower head 330, the fluorine-containing radicals (e.g., F*, NF₃*, etc.) in the second space 302 may be supplied to the processing space 101. Additionally, in accordance with a modification of this embodiment, the first and second reaction gases G2 and G3 may be supplied to the processing space 101.

In the processing space 101, the fluorine-containing radicals (e.g., F*, NF₃*, etc.) may react with (poly)silicon formed on the substrate W, as indicated by Chemical Formula 1 below.

Si+F*→SiF₄(g) (Chemical Formula 1)

Here, since the first gas G4 has already been supplied to the edge region W20 to prevent excessive silicon etching in the edge region W20, a reaction product of the first gas G1 and the process gas G1 may be formed in the edge region W20, unlike in the center region W10, as indicated by Chemical Formula 2 below.

F*+H₂→HF(g) (Chemical Formula 2)

In other words, the supply of the first gas G4 allows the fluorine density in the edge region W20 to be controlled.

After the second process time (after T2), when silicon etching is complete, the plasma may be turned off, and the supply of the first gas G4 and the process gas G1 may be stopped. The by-products may then be removed through the exhaust port formed in the bottom surface of the chamber unit 100.

As this embodiment involves etching silicon, it may not require a high-temperature environment for by-product removal, compared to the case of etching silicon oxide. That is, there is no need to set the environment to a temperature of 100° C. or higher for by-product removal, but the present disclosure is not limited thereto.

For example, the processing temperature may be in, but is not limited to, the range of 50° C. to 110° C., and the processing pressure may be in, but is not limited to, the range of 200 mTorr to 8 Torr.

In the substrate treating apparatus 10 and the substrate treating method according to this embodiment, as fluorine radicals react with polysilicon to form silicon tetrafluoride (SiF₄(g)), the first gas G4, a hydrogen-containing gas, is locally supplied from the lateral side of the chamber unit 100 to the edge region W20 of the substrate W. Consequently, the etch rate in the edge region W20 of the substrate W can be controlled, thereby improving the uniformity of the substrate W.

Although the embodiments of the present disclosure have been described with reference to the accompanying drawings, those skilled in the art will understand that various modifications can be made without departing from the technical idea or essential features of the present disclosure. Therefore, the embodiments described above should be considered in all respects as illustrative and not restrictive.

What is claimed is:

1. A substrate treating apparatus comprising:
a support unit supporting a substrate;
a process gas supply unit supplying a process gas for treating the substrate;
a chamber unit in which a processing space accommodating the support unit is formed and into which the process gas is introduced; and
a first gas supply module supplying a first gas for regulating the density of effluents from the process gas,
wherein the chamber unit includes a first gas exhaust hole discharging the first gas toward the substrate.

2. The substrate treating apparatus of claim 1, wherein the chamber unit includes: a chamber in which the processing space is formed; and a liner surrounding an inner circumferential surface of the chamber and including the first gas exhaust hole.

3. The substrate treating apparatus of claim 2, wherein a plurality of first gas exhaust holes are formed along a circumference of the liner.

4. The substrate treating apparatus of claim 3, wherein the liner further includes a first flow path in communication with the plurality of first gas exhaust holes, through which the first gas flows, the first flow path being connected to the first gas supply module.

5. The substrate treating apparatus of claim 1, wherein
the substrate includes a center region and an edge region at a periphery of the center region, and
the first gas supply module includes a first gas line through which the first gas flows, and which is configured or adjusted to regulate a fluid pressure and flow rate of the first gas such that the first gas is discharged to the edge region.

6. The substrate treating apparatus of claim 5, wherein the first gas line includes a pressure control unit regulating the fluid pressure of the first gas such that the first gas is discharged to the edge region.

7. The substrate treating apparatus of claim 6, wherein the pressure control unit includes an orifice.

8. The substrate treating apparatus of claim 7, wherein the orifice is configured to regulate the fluid pressure of the first gas such that not a first fluid pressure that discharges the first gas even to the center region, but a second fluid pressure that discharges the first gas to the edge region is formed, thereby equalizing an etch rate between the center region and the edge region

9. The substrate treating apparatus of claim 5, wherein the first gas line includes a valve regulating the flow rate of the first gas.

10. The substrate treating apparatus of claim 9, wherein the valve is configured to regulate the flow rate of the first gas such that not a first flow rate that discharges the first gas even to the center region, but a second flow rate that discharges the first gas to the edge region is formed, thereby equalizing an etch rate between the center region and the edge region.

11. The substrate treating apparatus of claim 2, further comprising:
a shower head provided above the chamber unit.

12. The substrate treating apparatus of claim 11, wherein
the process gas supply unit includes: an upper electrode connected to the process gas supply unit and having a first supply hole through which the process gas flows; and an ion blocker disposed below the upper electrode, with a first space formed between the ion blocker and the upper electrode to receive the process gas, the ion blocker including a first through-hole through which effluents of the process gas are discharged, and
the support unit includes an electrode plate serving as a lower electrode to form a plasma source together with the upper electrode.

13. The substrate treating apparatus of claim 12, wherein the shower head includes: a second space formed between the shower head and the ion blocker, and a second through-hole formed in the shower head and discharging effluents from the process gas from above the processing space.

14. The substrate treating apparatus of claim 11, wherein
the liner has an upper end bent outward to rest on the upper end of the chamber, and
one or more O-rings are further provided between the liner and the shower head and between the liner and the chamber.

15. The substrate treating apparatus of claim 1, wherein
the process gas includes a fluorine-containing gas, and
the first gas includes a hydrogen-containing gas that generates a fluorine scavenging effect.

16. The substrate treating apparatus of claim 15, wherein the first gas includes at least one of H₂, HBr, NH₃, or CH₄.

17. A substrate treating method comprising:
providing a substrate treating apparatus, the substrate treating apparatus including: a support unit supporting a substrate having a center region and an edge region at a periphery of the center region; a process gas supply unit supplying a process gas including a fluorine-containing gas to treat the substrate; a chamber unit in which a processing space accommodating the support unit is formed, into which the process gas is introduced, and which includes a first gas exhaust hole discharging a first gas for regulating a density of effluents from the process gas toward the substrate; a first gas supply module supplying the first gas; an upper electrode connected to the process gas supply unit and having a first supply hole through which the process gas flows; an ion blocker disposed below the upper electrode, with a first space formed between the ion blocker and the upper electrode to receive the process gas, the ion blocker including a first through-hole through which effluents from the process gas are discharged; and a shower head provided above the chamber unit, with a second space formed between the shower head and the ion blocker, the shower head including a second through-hole discharging effluents from the process gas from above the processing space;
supplying the first gas to the substrate through the first gas exhaust hole, not from above the shower head; and
supplying the process gas,
wherein the first gas includes a hydrogen-containing gas that generates a fluorine scavenging effect.

18. The substrate treating method of claim 17, wherein
in the providing the substrate treating apparatus, the chamber unit includes: a chamber in which the processing space is formed; and a liner surrounding an inner circumferential surface of the chamber, with a plurality of first gas exhaust holes formed along its circumference to discharge the first gas toward the substrate, and including a first flow path in communication with the plurality of first gas exhaust holes and connected to the first gas supply module,
the first gas supply module includes a first gas line through which the first gas flows and which supplies the first gas to the edge region of the substrate to equalize an etch rate between the center region and the edge region,
the first gas line includes: an orifice forming a second fluid pressure that discharges the first gas to the edge region without forming a first fluid pressure that discharges the first gas to the center region; and a valve forming a second flow rate that discharges the first gas to the edge region without forming a first flow rate that discharges the first gas to the center region, and
the supplying the first gas comprises supplying the first gas at the second fluid pressure and the second flow rate.

19. The substrate treating method of claim 17, wherein in the supplying the first gas, the first gas includes at least one of H₂, HBr, NH₃, or CH₄.

20. A substrate treating apparatus comprising:
a support unit supporting a substrate having a center region and an edge region at a periphery of the center region and including an electrode plate serving as a lower electrode;
a process gas supply unit supplying a process gas including a fluorine-containing gas to treat polysilicon formed on the substrate;
a chamber unit in which a processing space accommodating the support unit is formed and into which the process gas is introduced;
a first gas supply module supplying a first gas for regulating a density of effluents from the process gas;
an upper electrode connected to the process gas supply unit and having a first supply hole through which the process gas flows;
an ion blocker disposed below the upper electrode, with a first space formed between the ion blocker and the upper electrode to receive the process gas, the ion blocker including a first through-hole through which effluents from the process gas are discharged; and
a shower head provided above the chamber unit, with a second space formed between the shower head and the ion blocker, the shower head including a second through-hole discharging effluents from the process gas from above the processing space,
wherein
the chamber unit includes: a chamber in which the processing space is formed; and a liner surrounding an inner circumferential surface of the chamber, with a plurality of first gas exhaust holes formed along its circumference to discharge the first gas toward the substrate, and including a first flow path in communication with the plurality of first gas exhaust holes, through which the first gas flows, the first flow path being connected to the first gas supply module,
the first gas supply module includes a first gas line through which the first gas flows, the first gas line supplying the first gas to the edge region of the substrate to equalize an etch rate between the center region and the edge region,
the first gas line includes: an orifice forming a second fluid pressure that discharges the first gas to the edge region without forming a first fluid pressure that discharges the first gas to the center region; and a valve forming a second flow rate that discharges the first gas to the edge region without forming a first flow rate that discharges the first gas to the center region, and
the first gas includes a hydrogen-containing gas that generates a fluorine scavenging effect and includes at least one of H₂, HBr, NH₃, or CH₄.
